(19) United States
(12) Patent Application Publication
(10) Pub. No.: US 2008/0143421 A1
(43) Pub. Date: Jun. 19, 2008

(54) Bidirectional switch and method for driving bidirectional switch

(76) Inventors: Manabu Yanagihara, Osaka (JP); Tatsuo Morita, Kyoto (JP); Yasuhiro Uemoto, Shiga (JP)

Correspondence Address: MCDERMOTT WILL & EMERY LLP, 600 13TH STREET, NW, WASHINGTON, DC, 20005-3096, US

(21) Appl. No.: 11/979,405

(22) Filed: Nov. 2, 2007

(30) Foreign Application Priority Data
Dec. 14, 2006 (JP) 2006-336952

(51) Int. Cl. H03K 17/687

(52) U.S. Cl. 327/427

(57) ABSTRACT

A bidirectional switch comprises a first FET, a second FET, and a switch controller for controlling a conductive state in which current from a bidirectional power supply electrically connected to drain terminals bidirectionally flows, and a nonconductive state in which the current does not flow. In the conductive state, the switch controller applies, to gate terminals of the first FET and the second FET, a voltage higher than a threshold voltage with reference to a potential at a node to which source terminals of the first FET and the second FET are connected. In the nonconductive state, the switch controller causes the bidirectional power supply and each gate terminal to be electrically insulated from each other, and applies a voltage lower than or equal to the threshold voltage with reference to the potential at the node.

### CROSS REFERENCE TO RELATED APPLICATIONS

This Non-provisional application claims priority under 35 U.S.C. §119(a) on Patent Application No. 2006-336952 filed in Japan on Dec. 14, 2006, the entire contents of which are hereby incorporated by reference.

### BACKGROUND OF THE INVENTION

1. Field of the Invention

The present invention relates to a bidirectional switch having a low ON-resistance and a method for driving the bidirectional switch.

2. Description of the Related Art

There are known switching power semiconductor devices, such as a power MOS FET (Metal Oxide Film Semiconductor Field-Effect Transistor), an IGBT (Insulated Gate Bipolar Transistor), a thyristor, a triac, and the like. When these semiconductor devices are used to form a switching circuit capable of provide bidirectional current flow, the semiconductor devices need bidirectional high breakdown voltages.

Power MOS FETs and IGBTs generally have a low reverse breakdown voltage. Therefore, a bidirectional switch may be, for example, formed as follow: two IGBTs are connected in inverse parallel (in parallel but with their polarities reversed) while a diode is connected to each IGBT in series as shown in FIG. 11. The same is true of power MOS FETs. In FIG. 11, an IGBT 201 and a diode 202, and an IGBT 203 and a diode 204, are connected in inverse parallel. Therefore, when the IGBT 201 and the IGBT 203 are both in the ON state, current bidirectionally flows. When the IGBT 201 and the IGBT 203 are both in the OFF state, a high bidirectional breakdown voltage can be attained.

Triacs are a bidirectional switch which employs a single semiconductor device. In the triac, unless a signal is applied to the gate, current does not flow even when a voltage is applied with either polarity. When trigger current is caused to flow the gate, the triac goes to the ON state. The ON state is maintained until a voltage is applied with the polarity reversed. Because of such a property, the triac is used to switch alternating power as shown in FIG. 12. The triac is connected to a load and an alternating power supply in series, and perform switching of a voltage applied to the load by a gate control circuit. Since a single triac can perform switching of alternating power, it is possible to achieve a compact and low-cost circuit.

However, in the conventional bidirectional switch of FIG. 11, in addition to an IGBT or a MOS FET, a diode which is connected to the IGBT or MOS FET in series is required. As a result, when the switch is in the ON state, power loss occurs due to the ON-resistance of the diode in addition to power loss due to the ON-resistance of the IGBT or MOS FET. Further, the increased number of elements causes an increase in cost.

Also, in a bidirectional switch which employs a conventional triac or the like, there is a limit on a reduction in the ON-resistance due to the material limit of Si.

Also, a bidirectional switch has been proposed which employs a semiconductor device having a common electrode for fixing a potential of a semiconductor substrate, where the common electrode is provided on a rear surface of the semiconductor substrate (see, for example, Japanese Unexamined Patent Application Publication No. 2006-165387). In this case, excessively large current may flow through the gate, likely leading to breakdown of the device. Although the common electrode is provided on the rear surface of the substrate, it is difficult to drive the gate if a high-resistance buffer layer is present.

### SUMMARY OF THE INVENTION

The present invention is provided to solve the above-described conventional problems. An object of the present invention is to provide a bidirectional switch which does not require a diode which is conventionally connected in series and can achieve a low ON-resistance and low power loss.

To achieve the object, the present invention provides a bidirectional switch comprising a switch controller for applying a bias voltage to gate terminals of two FETs whose source terminals are connected together, where a potential of a node at which source electrodes are connected together.

A first bidirectional switch according to the present invention comprises a first field-effect transistor having a first gate terminal, a first drain terminal, and a first source terminal, a second field-effect transistor having a second gate terminal, a second drain terminal, and a second source terminal electrically connected to the first source terminal, and a switch controller for controlling a conductive state in which current from a bidirectional power supply electrically connected between the first drain terminal and the second drain terminal bidirectionally flows between the first drain terminal and the second drain terminal, and a nonconductive state in which the current does not flow between the first drain terminal and the second drain terminal. In the conductive state, the switch controller applies, to the first gate terminal and the second gate terminal, a voltage higher than a threshold voltage of the first field-effect transistor and the second field-effect transistor with reference to a potential at a node at which the first source terminal and the second source terminal are connected. In the nonconductive state, the switch controller causes the bidirectional power supply and the first and the second gate terminals to be electrically insulated from each other, and applies, to the first gate terminal and the second gate terminal, a voltage lower than or equal to the threshold voltage with reference to the potential at the node.

According to the first bidirectional switch, a forward voltage which is required to cause diode components which are generated between the first gate terminal and the first drain terminal and between the second gate terminal and the second drain terminal to go to the ON state is not applied to the first gate terminal and the second gate terminal. Therefore, excessively large gate current does not flow through the first gate terminal or the second gate terminal. As a result, a diode which is connected in series is not required, thereby making it possible to achieve a bidirectional switch having a low ON-resistance and small power loss.

A second bidirectional switch according to the present invention comprises a semiconductor device having a semiconductor layer formed on a major surface of a semiconductor substrate and including a channel region in which electrons travel in a direction parallel to the major surface is formed, a first ohmic electrode, a gate electrode, a first reference electrode, and a second ohmic electrode which are spaced from each other and successively formed on the semiconductor layer, and a second reference electrode formed on a surface opposite to the major surface of the semiconductor substrate, and a switch controller for controlling a conductive state in which current from a bidirectional power supply electrically connected between the first ohmic electrode and the second ohmic electrode bidirectionally flows between the first ohmic electrode and the second ohmic electrode, and a nonconductive state in which the current does not flow between the first ohmic electrode and the second ohmic electrode. In the conductive state, the switch controller applies, to the gate electrode, a voltage higher than a threshold voltage of the semiconductor device with reference to a potential of the first reference electrode. In the nonconductive state, the switch controller short-circuits the gate electrode and the second reference electrode.

According to the second bidirectional switch, a large forward bias which causes a pn junction to go to the ON state is not applied between the gate electrode and the first ohmic electrode or the second ohmic electrode. Therefore, excessively large gate current does not flow, so that the bidirectional switching device is not broken down. Also, in the conductive state, a voltage with reference to the potential of the first reference electrode formed on the semiconductor layer is applied to the gate electrode, thereby making it possible to reliably drive the gate.

A first method according to the present invention for driving a bidirectional switch comprising a first field-effect transistor having a first gate terminal, a first drain terminal, and a first source terminal, and a second field-effect transistor having a second gate terminal, a second drain terminal, and a second source terminal electrically connected to the first source terminal, comprises a conduction step of applying, to the first gate terminal and the second gate terminal, a voltage higher than a threshold of the first field-effect transistor and the second field-effect transistor with reference to a potential at a node to which the first source terminal and the second source terminal are connected, so that current from a bidirectional power supply electrically connected between the first drain terminal and the second drain terminal bidirectionally flows between the first drain terminal and the second drain terminal, and an interruption step of applying, to the first drain terminal and the second drain terminal, a voltage lower than or equal to the threshold voltage with reference to the potential of the node, in a state in which the bidirectional power supply is electrically insulated from the first gate terminal and the second gate terminal, so that current does not flow between the first drain terminal and the second drain terminal.

According to the first bidirectional switch driving method, a forward voltage which is required to cause diode components which are generated between the first gate terminal and the first drain terminal and between the second gate terminal and the second drain terminal to go to the ON state is not applied to the first gate terminal and the second gate terminal. Therefore, excessively large gate current does not flow through the first gate terminal or the second gate terminal. As a result, a diode which is connected in series is not required, thereby making it possible to achieve a bidirectional switch having a low ON-resistance and small power loss.

A second method according to the present invention for driving a bidirectional switch comprising a semiconductor device having a semiconductor layer formed on a major surface of a semiconductor substrate and including a channel region in which electrons travel in a direction parallel to the major surface is formed, a first ohmic electrode, a gate electrode, a first reference electrode, and a second ohmic electrode which are spaced from each other and successively formed on the semiconductor layer, and a second reference electrode formed on a surface opposite to the major surface of the semiconductor substrate, comprises a conduction step of applying, to the gate electrode, a voltage higher than a threshold of the semiconductor device with reference to a potential of the first reference electrode, so that current from a bidirectional power supply electrically connected between the first ohmic electrode and the second ohmic electrode bidirectionally flows between the first ohmic electrode and the second ohmic electrode, and an interruption step of short-circuiting the first gate electrode and the second gate electrode so that current does not flow between the first ohmic electrode and the second ohmic electrode.

According to the second bidirectional switch driving method, the gate potential is fixed to the potential of the second reference electrode, and the potential of the second reference electrode is a floating potential. Therefore, a large forward bias which causes a pn junction to go to the ON state is not applied between the gate electrode and the first ohmic electrode or the second ohmic electrode. Therefore, excessively large gate current does not flow, so that the bidirectional switching device is not broken down.

### BRIEF DESCRIPTION OF THE DRAWINGS

FIG. 1 is a circuit diagram showing a bidirectional switch according to a first embodiment of the present invention.

FIG. 2 a circuit configuration diagram showing a bidirectional switch according to a variation of the first embodiment of the present invention.

FIG. 3 is a circuit configuration diagram showing a bidirectional switch according to a second embodiment of the present invention.

FIG. 4 a circuit configuration diagram showing a bidirectional switch according to a variation of the second embodiment of the present invention.

FIG. 5 is a cross-sectional view showing a variation of a bidirectional switching device for use in the bidirectional switch of the second embodiment of the present invention.

FIG. 6 is a cross-sectional view showing a variation of a bidirectional switching device for use in the bidirectional switch of the second embodiment of the present invention.

FIG. 7 is a cross-sectional view showing a variation of a bidirectional switching device for use in the bidirectional switch of the second embodiment of the present invention.

FIG. 8 is a circuit configuration diagram according to a variation of the second embodiment of the present invention.

FIG. 9 is a plan view showing a bidirectional switching device for use in the bidirectional switch of the second embodiment of the present invention.

FIG. 10 is a cross-sectional view showing a bidirectional switching device for use in a bidirectional switch according to a third embodiment of the present invention.

FIG. 11 is a circuit diagram showing a conventional bidirectional switch.

FIG. 12 is a circuit diagram showing a conventional bidirectional switch.

### DETAILED DESCRIPTION OF THE PREFERRED EMBODIMENTS

### First Embodiment

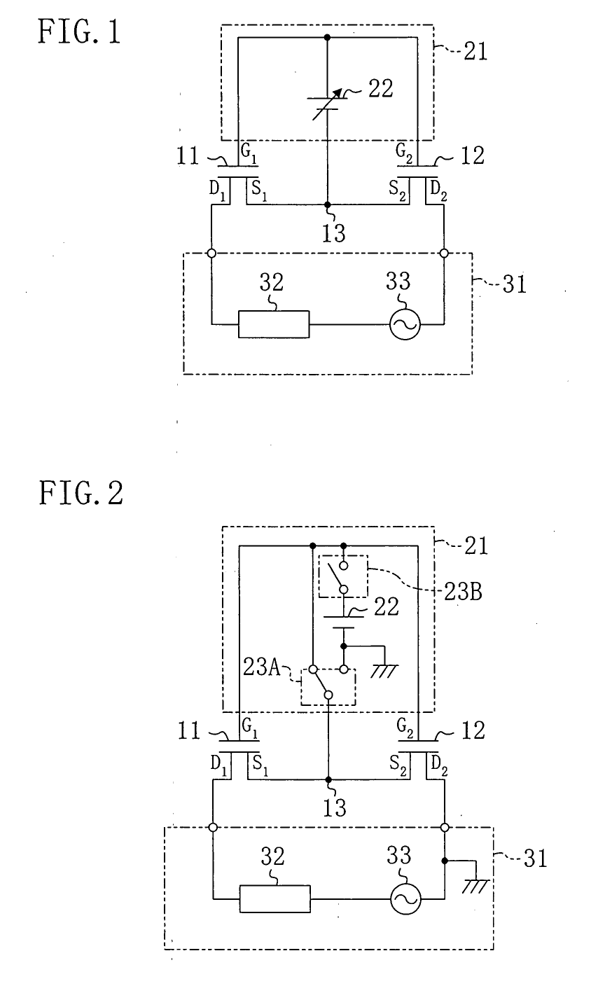

A first embodiment of the present invention will be described with reference to the accompanying drawings. FIG. 1 shows a circuit configuration of a bidirectional switch according to the first embodiment.

The bidirectional switch of the first embodiment comprises a first field-effect transistor (FET) 11 and a second FET 12 whose source terminals are connected to each other, and a switch controller 21 for applying a bias voltage to gate terminals of the first FET 11 and the second FET 12.

A load circuit 31 in which a load 32 and an alternating power supply 33 (bidirectional power supply) are connected in series is connected between a drain terminal D1 of the first FET 11 and a drain terminal D2 of the second FET 12. The bidirectional power supply is a power supply which can provide a bidirectional current flow, including, for example, a circuit configuration which can provide a bidirectional current flow in addition to an alternating power supply. For example, a resonant circuit formed of capacitances and inductances may be considered as a bidirectional power supply. Such a resonant circuit is used in, for example, a drive circuit for a plasma display panel.

The switch controller 21 has a node 13 to which a source terminal S1 of the first FET 11 and a source terminal S2 of the second FET 12 are connected, and a control power supply 22 which is connected between a gate terminal G1 of the first FET 11 and a gate terminal G2 of the second FET 12. The control power supply 22 is insulated from the alternating power supply 33, and can vary its output voltage (variable power supply).

Hereinafter, an operation of the bidirectional switch of this embodiment will be described. Note that the first FET 11 and the second FET 12 are assumed to be, for example, of the normally OFF type.

Initially, when a voltage of the control power supply 22 is 0 V and voltages of the gate terminal G1 of the first FET 11 and the gate terminal G2 of the second FET 12 are 0 V with respect to the node 13, the first FET 11 and the second FET 12 are in the OFF state. Therefore, current does not flow between the drain terminal D1 of the first FET 11 and the drain terminal D2 of the second FET 12.

In this situation, when a positive voltage is applied to the drain terminal D1 while a negative voltage is applied to the drain terminal D2, almost the whole voltage difference occurs between the drain terminal D1 and the source terminal S1, while a voltage difference between the drain terminal D2 and the source terminal S2 is small. The reason is as follows. Since a forward bias is applied to a diode component which is generated between the gate terminal G2 and the drain terminal D2, current may flow from the gate terminal G2 to the drain terminal D2. However, the control power supply 22 is insulated from the alternating power supply 33 and the ground. Therefore, the gate terminal G2 is electrically insulated from the alternating power supply 33, i.e., there is not a current supply source, so that the diode component between the gate terminal G2 and the drain terminal D2 does not go to the ON state.

Conversely, when a negative voltage is applied to the drain terminal D1 while a positive voltage is applied to the drain terminal D2, almost the whole voltage difference occurs between the drain terminal D2 and the source terminal S2, while a voltage difference between the drain terminal D1 and the source terminal S1 is small. Therefore, in this case, a diode component which is generated between the gate terminal G1 and the drain terminal D1 does not go to the ON state.

Thus, a potential at the node 13 varies, depending on the polarity of a voltage applied between the drain terminal D1 and the drain terminal D2. Therefore, a forward voltage is not applied which is required to cause the diode components which are generated between the gate terminal G1 and the drain terminal D1 and between the gate terminal G2 and the drain terminal D2 to go to the ON state, so that excessively large gate current does not flow through the gate terminal G1 or the gate terminal G2.

On the other hand, when the voltages of the gate terminal G1 and the gate terminal G2 with reference to the potential at the node 13 are set to be higher than a threshold voltage, the first FET 11 and the second FET 12 simultaneously go to the ON state, so that current bidirectionally flows between the drain terminal D1 and the drain terminal D2.

Since the bidirectional switch of this embodiment does not require a protection diode, a low-loss bidirectional switch is achieved. Also, if an FET employing a nitride semiconductor or silicon carbide is used, the ON-resistance can be further reduced, so that the conduction loss of the bidirectional switch can be extremely reduced.

Note that the control power supply 22 may be a direct-current power supply having a floating ground, such as a battery or the like. Alternatively, the control power supply 22 may be an insulated voltage converting circuit (isolated DC-DC converter). Even when a voltage is supplied from a first power supply to the input side of the isolated DC-DC converter, a voltage which is insulated from the input side is output from the output side, so that a control power supply and an alternating power supply can be insulated from each other.

### Variation of First Embodiment

Hereinafter, a variation of the first embodiment will be described with reference to the drawings. FIG. 2 shows a circuit configuration of a bidirectional switch according to the variation of the first embodiment. In FIG. 2, the same parts as those of FIG. 1 are indicated by the same reference numerals and will not be described.

As shown in FIG. 2, in the bidirectional switch of this variation, the switch controller 21 is configured such that the control power supply 22 can be cut off from the circuit, and the node 13 and the gate terminal G1 and the gate terminal G2 can be short-circuited.

Specifically, the control power supply 22 is connected via a first switch 23A to the node 13, and via a second switch 23B to the gate terminal G1 and the gate terminal G2. The first switch 23A and the second switch 23B can be switched together so that the control power supply 22 can be cut off from the switch controller 21. The first switch 23A is a single-pole double-throw switch, and short-circuits the node 13 and the gate terminal G1 and the gate terminal G2 when the control power supply 22 is cut off. In this variation, the control power supply 22 does not need to be insulated from the alternating power supply 33, and may be a typical power supply whose negative pole is grounded.

In the bidirectional switch of this variation, in order to cause current to flow between the drain terminal D1 and the drain terminal D2 (conductive state), the control power supply 22 is connected to the switch controller 21. Thereby, since a voltage higher than or equal to the threshold voltage is applied to each of the gate terminal G1 and the gate terminal G2, the first FET 11 and the second FET 12 both go to the ON state.

In order to interrupt the flow of current between the drain terminal D1 and the drain terminal D2, the first switch 23A and the second switch 23B are switched so that the control power supply 22 is cut off from the switch controller 21 while the node 13 and the gate terminal G1 and the gate terminal G2 are short-circuited. Thereby, the gate terminal G1 and the gate terminal G2 are insulated from the alternating power supply 33, so that the gate terminal G1 and the gate terminal G2 have the same potential as that of the node 13.

In the nonconductive state, since the gate terminal G1 and the gate terminal G2 are cut off from the control power supply, there is not a current supply source which causes current to flow from the gate terminal G1 to the drain terminal D1 or from the gate terminal G2 to the drain terminal D2. Therefore, as in the first embodiment, the potential of the node 13 varies, depending on the polarity of a voltage applied between the drain terminal D1 and the drain terminal D2. Therefore, a forward voltage is not applied which is required to cause diode components which are generated between the gate terminal G1 and the drain terminal D1 and between the gate terminal G2 and the drain terminal D2 to go to the ON state, so that excessively large gate current does not flow through the gate terminal G1 or the gate terminal G2.

In this variation, a typical power supply which shares a ground with the alternating power supply 33 can be advantageously employed as the control power supply 22.

As the first switch 23A and the second switch 23B, a switch having a high insulation property needs to be employed. For example, an optical isolation switch having a photocoupler may be employed. Alternatively, a mechanical switch or an electrical switch having a high level of isolation may be employed.

### Second Embodiment

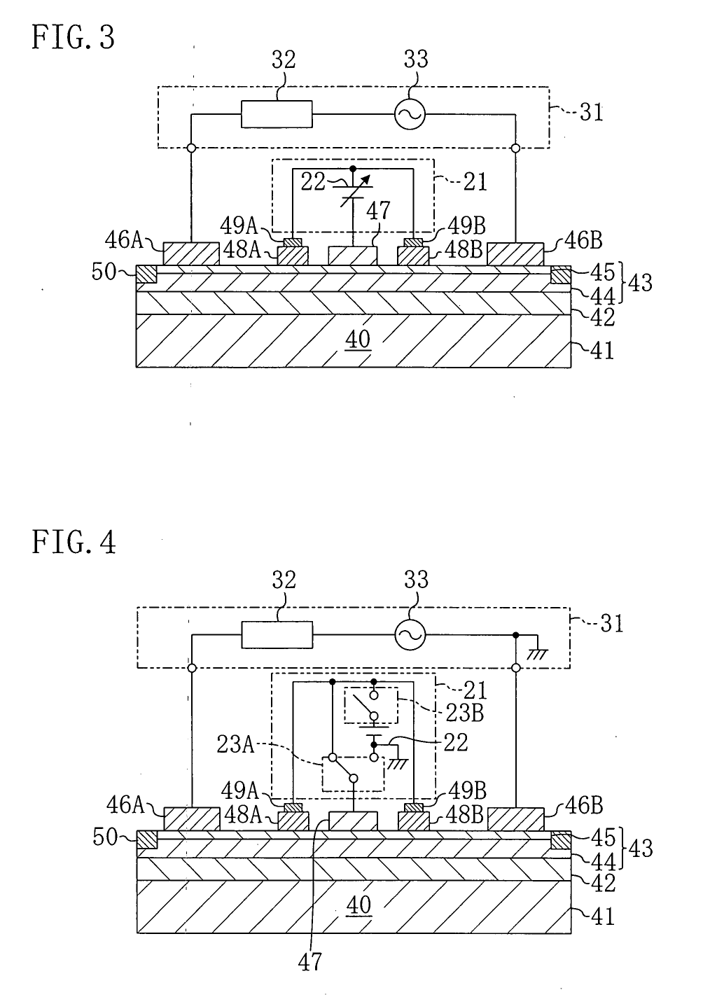

Hereinafter, a second embodiment of the present invention will be described with reference to the drawings. FIG. 3 shows a circuit configuration of a bidirectional switch according to the second embodiment. In FIG. 3, the same parts as those of FIG. 1 are indicated by the same reference numerals and will not be described. The bidirectional switch of this embodiment is different from the bidirectional switch of the first embodiment in that the first FET 11 and the second FET 12 are replaced with a single bidirectional switching device 40.

As shown in FIG. 3, the bidirectional switching device 40 has a substrate 41 made of silicon (Si) or the like, a buffer layer 42, and a semiconductor layer 43, where the semiconductor layer 43 is formed via the buffer layer 42 on the substrate 41. The semiconductor layer 43 comprises an undoped GaN layer 44 and an undoped AlGaN layer 45 which are epitaxially grown in this order from below. In an interface region of the undoped GaN layer 44 with respect to the undoped AlGaN layer 45, a two-dimensional electron gas (2DEG) layer which serves as a channel region is formed due to an influence of spontaneous polarization and piezoelectric polarization. The 2DEG layer has a carrier concentration of about 1×10¹³ cm⁻² when it is assumed that, for example, the undoped GaN layer 44 has a thickness of 2 μm and the undoped AlGaN layer 45 has an Al molar ratio of 15% and a Ga molar ratio of 85% and has a thickness of 25 nm.

In the semiconductor layer 43, a first ohmic electrode 46A, a reference electrode 47, and a second ohmic electrode 46B are provided and spaced from each other. The first ohmic electrode 46A, the reference electrode 47, and the second ohmic electrode 46B are a multilayer of titanium (Ti) and aluminum (Al), and are in ohmic-contact with the 2DEG layer.

A first gate electrode 49A is formed via a first p-type semiconductor layer 48A on the undoped AlGaN layer 45 and between the first ohmic electrode 46A and the reference electrode 47. A second gate electrode 49B is formed via a second p-type semiconductor layer 48B between the second ohmic electrode 46B and the reference electrode 47. The first gate electrode 49A and the second gate electrode 49B are a multilayer of palladium (Pd), Ti, and gold (Au), and are in ohmic-contact with the first p-type semiconductor layer 48A and the second p-type semiconductor layer 48B, respectively.

The bidirectional switching device 40 is equivalent to two FETs whose source electrodes are connected to each other. Therefore, the first ohmic electrode 46A corresponds to the drain terminal D1 of the first FET 11 of FIG. 1, and the second ohmic electrode 46B corresponds to the drain terminal D2 of the second FET 12. The reference electrode 47 corresponds to the source terminal S1 and the source terminal S2 which are electrically connected to each other, and the first gate electrode 49A and the second gate electrode 49B correspond to the gate terminal G1 and the gate terminal G2, respectively.

In this embodiment, in order to obtain the normally OFF type, the first p-type semiconductor layer 48A and the second p-type semiconductor layer 48B are formed between the first gate electrode 49A and the second gate electrode 49B, and the undoped AlGaN layer 45, respectively. The first p-type semiconductor layer 48A and the second p-type semiconductor layer 48B may be, for example, a p-type doped AlGaN layer having a carrier concentration of 1×10¹⁸ cm⁻³. Thereby, a pn junction is formed between the first p-type semiconductor layer 48A and the second p-type semiconductor layer 48B, and the 2DEG layer, so that the bidirectional switching device 40 is of the normally OFF type.

The breakdown voltage of the bidirectional switch when it is OFF is determined, depending on a distance between the first ohmic electrode 46A and the first p-type semiconductor layer 48A and a distance between the second ohmic electrode 46B and the second p-type semiconductor layer 48B. When switching is performed with respect to a power supply of several hundreds of voltage, the distances may be preferably about 5 μm to 10 μm.

Note that, as shown in FIG. 3, this embodiment shows that the bidirectional switching device 40 is formed in a bidirectional device formed region isolated from the surroundings by a high-resistance region 50 whose resistance is increased by implanting an ions to the semiconductor layer 43.

The first p-type semiconductor layer 48A and the second p-type semiconductor layer 48B are shaped into a mesa in the bidirectional device formed region. A gate length of the bidirectional switching device 40 is determined, depending on lengths of the first p-type semiconductor layer 48A and the second p-type semiconductor layer 48B. The lengths of the first p-type semiconductor layer 48A and the second p-type semiconductor layer 48B are preferably about 1 μm to 3 μm. The shorter the lengths of the first ohmic electrode 46A and the second ohmic electrode 46B, the smaller the area of the bidirectional switching device 40. However, a certain length is required to obtain a large current flow, and therefore, is preferably about 3 μm to 10 μm. Since little current flows through the reference electrode 47, the length is preferably about 2 μm to 5 μm.

In this embodiment, a bidirectional switch is achieved by a single semiconductor device, so that the number of parts can be reduced. Also, since the semiconductor device is formed of a nitride semiconductor, the ON-resistance can be further reduced.

Although it has been assumed in this embodiment that the switch controller 21 is the same circuit as that of the first embodiment, the switch controller 21 of the variation of the first embodiment may be employed as shown in FIG. 4.

Although it has been assumed in this embodiment that the semiconductor device is of the normally OFF type, a semiconductor device of the normally ON type can be similarly employed. In this case, a potential which is negative with respect to the reference electrode 47 may be applied to the first gate electrode 49A and the second gate electrode 49B so as to achieve the nonconductive state, and a potential which is sufficiently higher than the negative potential applied for the nonconductive state may be applied thereto so as to achieve the conductive state.

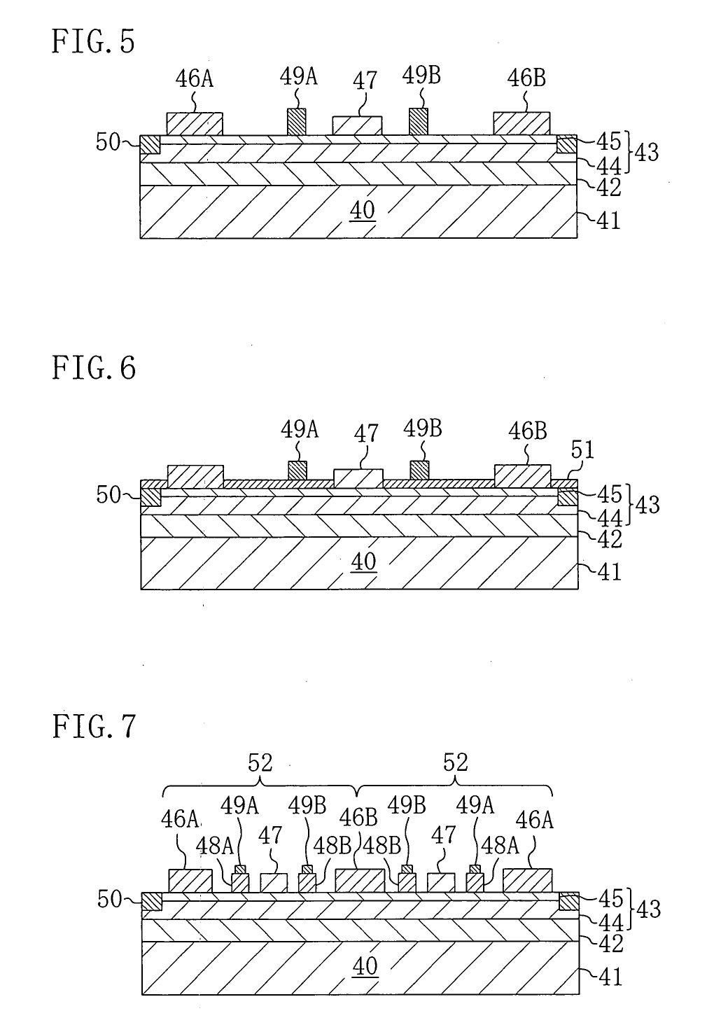

Although a semiconductor device has been assumed in this embodiment in which the first gate electrode 49A and the second gate electrode 49B are in ohmic-contact with the first p-type semiconductor layer 48A and the second p-type semiconductor layer 48B, respectively, a semiconductor device may be employed in which the first gate electrode 49A and the second gate electrode 49B may be in Schottky-contact with the undoped AlGaN layer 45 as shown in FIG. 5. In this case, in order to obtain a semiconductor device of the normally OFF type, for example, the Al molar ratio and the Ga molar ratio of the undoped AlGaN layer 45 may be 10% and 90%, respectively, so as to reduce the influence of piezoelectric polarization.

Also, a semiconductor device having a metal-insulator-semiconductor (MIS) structure may be employed in which a silicon nitride film 51 having a thickness of 5 nm is formed between the first gate electrode 49A and the second gate electrode 49B, and the undoped AlGaN layer 45 as shown in FIG. 6. Also in this case, a semiconductor device of the normally OFF type can be achieved by reducing the influence of piezoelectric polarization.

Further, as shown in FIG. 7, a structure ranging from the first ohmic electrode 46A to the second ohmic electrode 46B is referred to as a unit 52. A plurality of units 52 may be repeatedly arranged (any adjacent units 52 are mirror-symmetrical to each other) to provide a semiconductor device having a multi-finger structure. With such a structure, it is possible to achieve a large current flow.

Although it has been assumed in this embodiment that the substrate 41 is made of Si, the substrate may be made of sapphire or silicon carbide (SiC), on which a nitride semiconductor can be grown.

Although it has been assumed in this embodiment that the bidirectional switching device 40 is made of a nitride semiconductor as a major semiconductor material, SiC may be used.

### Variation of Second Embodiment

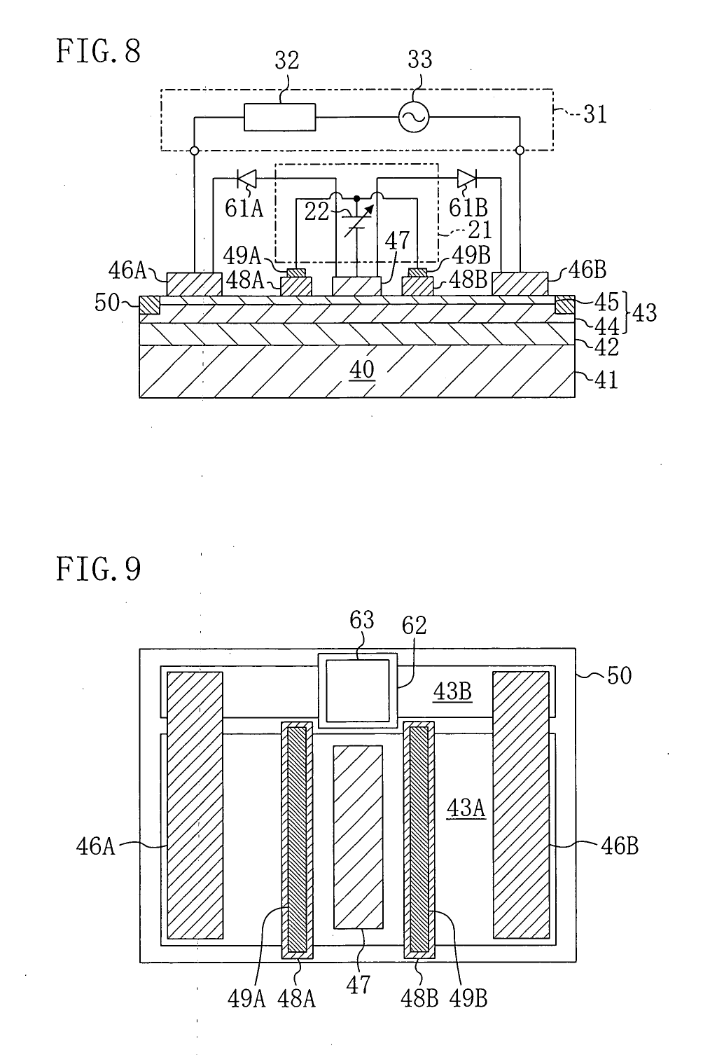

Hereinafter, a variation of the second embodiment will be described with reference to the drawings. FIG. 8 shows a configuration of a bidirectional switch according to the variation of the second embodiment. In FIG. 8, the same parts as those of FIG. 3 are indicated by the same reference numerals and will not be described.

The bidirectional switch of this variation has a first diode 61A connected between the first ohmic electrode 46A and the reference electrode 47 and a second diode 61B between the second ohmic electrode 46B and the reference electrode 47.

The first diode 61A and the second diode 61B are a free-wheel diode for preventing excessively large current from being applied to the bidirectional switching device 40 at the instant when the bidirectional switch is turned OFF (where the load 32 is an inductive load (L load)), thereby avoiding breakdown of the bidirectional switch.

The first diode 61A and the second diode 61B may be a typical pn-junction diode device, a Schottky diode device, or the like. In the following case, the first diode 61A and the second diode 61B can be formed integrally with the bidirectional switching device 40.

FIG. 9 shows an exemplary two-dimensional configuration of a semiconductor device in which the bidirectional switching device 40 and the first diode 61A and the second diode 61B are integrally formed and which is used in the bidirectional switch of the variation of the second embodiment. The bidirectional switching device 40 is formed in a bidirectional switching device formed region 43A surrounded by the high-resistance region 50 in the semiconductor layer 43.

On a diode formed region 43B which is isolated via the high-resistance region 50 from the bidirectional switching device formed region 43A in the semiconductor layer 43, an anode electrode 63 is formed via a p-type semiconductor layer 62 for diode formation. The first ohmic electrode 46A and the second ohmic electrode 46B are formed and extended over the bidirectional switching device formed region 43A and the diode formed region 43B. A pn junction is formed between the diode-forming p-type semiconductor layer 62 and the 2DEG layer. Therefore, the anode electrode 63 is shared by the first diode 61A and the second diode 61B, and portions formed in the diode formed region 43B of the first ohmic electrode 46A and the second ohmic electrode 46B serve as cathode electrodes of the first diode 61A and the second diode 61B, respectively.

Thus, the first diode 61A and the second diode 61B are formed integrally with the bidirectional switching device 40, thereby making it possible to reduce the size of the bidirectional switch. The number of parts can also be reduced.

Note that the switch controller 21 may have the first switch 23A and the second switch 23B, and the control power supply 22 and the alternating power supply 33 have a ground in common, as shown in FIG. 4,

### Third Embodiment

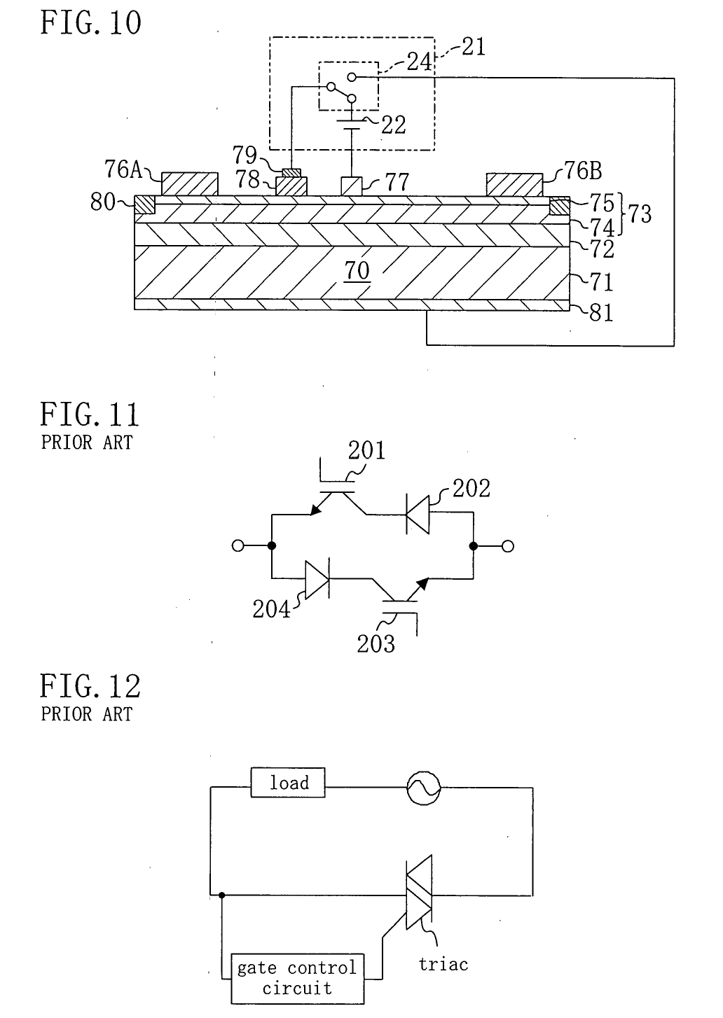

Hereinafter, a third embodiment of the present invention will be described with reference to the drawings. FIG. 10 shows a configuration of a bidirectional switch according to the third embodiment.

As shown in FIG. 10, the bidirectional switch of this embodiment comprises a bidirectional switching device 70 and a switch controller 21. The bidirectional switching device 70 has a semiconductor layer 73 which is grown via a buffer layer 72 on a substrate 71 made of silicon (Si) or the like. The semiconductor layer 73 includes an undoped GaN layer 74 having a thickness of 2 μm and an undoped AlGaN layer 75 having a thickness of 25 nm, which are epitaxially grown in this order from below. In an interface region of the undoped GaN layer 44 with respect to the undoped AlGaN layer 45, a 2DEG layer which serves as a channel region is formed due to an influence of spontaneous polarization and piezoelectric polarization.

A first ohmic electrode 76A and a second ohmic electrode 76B which are made of Ti and Al and are in ohmic-contact with the 2DEG layer are formed in a region isolated by a high-resistance region 80 in the semiconductor layer 73 and are spaced from each other. A p-type semiconductor layer 78 which is made of AlGaN (doped into p type) is epitaxially grown and formed between the first ohmic electrode 76A and the second ohmic electrode 76B. A pn junction is formed between the p-type semiconductor layer 78 and the 2DEG layer. A gate electrode 79 which is made of Pd, Ti and Au and is in ohmic-contact with the p-type semiconductor layer 78 is formed on the p-type semiconductor layer 78.

A first reference electrode 77 made of Ti and Al is formed between the p-type semiconductor layer 78 and the second ohmic electrode 76B. A second reference electrode 81 is formed on a rear surface of the substrate 71. The first reference electrode 77 is in ohmic-contact with the 2DEG layer, and the second reference electrode 81 is in ohmic-contact with the Si substrate.

A distance between the first ohmic electrode 76A and the p-type semiconductor layer 78 and a distance between the second ohmic electrode 76B and the p-type semiconductor layer 78 are determined, depending on a required breakdown voltage. When a breakdown voltage of several hundreds of voltage which is bidirectionally equal is required, the distance between the first ohmic electrode 76A and the p-type semiconductor layer 78 and the distance between the second ohmic electrode 76B and the p-type semiconductor layer 78 are set to be equal to each other (preferably, about 5 μm to 10 μm). A gate length of the bidirectional switching device 70 is determined, depending on a length of the p-type semiconductor layer 78 which is formed in the shape of a mesa, and is preferably about 1 μm to 3 μm. The shorter the lengths of the first ohmic electrode 76A and the second ohmic electrode 76B, the smaller the area of the bidirectional switching device 70. However, a certain length is required to obtain a large current flow, and therefore, is preferably about 3 μm to 10 μm. Since little current flows through the first reference electrode 77, the length is preferably about 2 μm to 5 μm.

The switch controller 21 has a control power supply 22 which is electrically connected to the first reference electrode 77, and a switch 24 which performs switching so as to electrically connect the gate electrode 79 to the control power supply 22 or the second reference electrode 81.

Hereinafter, an operation of the bidirectional switch of the third embodiment will be described. Note that a load circuit having an alternating power supply is connected between the first ohmic electrode 76A and the second ohmic electrode 76B, though not illustrated.

In the bidirectional switch of the third embodiment, when current does not flow between the first ohmic electrode 76A and the second ohmic electrode 76B (nonconductive state), a bias voltage with reference to the second reference electrode 81 formed on the rear surface of the substrate 71 is applied to the gate electrode 79. When current flows between the first ohmic electrode 76A and the second ohmic electrode 76B (conductive state), a bias voltage with reference to the first reference electrode formed on the semiconductor layer 73 is applied to the gate electrode 79.

When the conductive state and the nonconductive state are arranged to be switched by connecting a power supply between the gate electrode and the electrode provided on the rear surface of the substrate without using the first reference electrode 77, an excessively large current flows through the gate electrode in the nonconductive state for the following reason, likely leading to the device. In the nonconductive state, a high negative voltage is applied to either the first ohmic electrode or the second ohmic electrode. As a result, excessively large forward current flows between the gate electrode and the electrode to which the high negative voltage is applied. For example, in the case of a switching circuit for a commercial power supply having an alternating voltage of 100 V (in Japan), a forward voltage exceeding 140 V is applied.

However, in the bidirectional switch of this embodiment, when current does not flow between the first ohmic electrode 76A and the second ohmic electrode 76B (nonconductive state), the gate electrode 79 and the second reference electrode 81 are short-circuited by the switch 24. Although the buffer layer 72 having a high resistance is provided between the second reference electrode 81 and the 2DEG layer, since current does not need to flow between the second reference electrode 81 and the gate electrode 79, the gate potential is fixed to a potential of the second reference electrode 81. The potential of the second reference electrode 81 is a floating potential, a large forward bias which causes a pn junction to go to the ON state is not applied between the gate electrode 79 and the first ohmic electrode 46A or the second ohmic electrode 46B. Therefore, excessively large gate current does not flow, so that the bidirectional switching device 70 is not broken down.

On the other hand, when a voltage with reference to the electrode provided on the rear surface of the substrate (the first reference electrode is not provided) is applied to the gate electrode so as to achieve the conductive state, it is difficult to sufficiently drive the gate due to the presence of the buffer layer having a high resistance.

However, in the bidirectional switch of this embodiment, the switch 24 is used to connect the gate electrode 79 to the control power supply 22 which is connected to the first reference electrode 77 provided on the semiconductor layer 73. Therefore, the presence of the buffer layer 72 does not raise a problem, and a voltage with reference to the first reference electrode 77 is applied from the control power supply 22 to the gate electrode 79. Therefore, since the 2DEG layer is formed below the p-type semiconductor layer 78 which the gate electrode 79 contact, thereby making it possible to reduce the ON-resistance.

Note that, also in this embodiment, the bidirectional switching device 70 may be arranged to have a gate electrode which is Schottky-contact with the semiconductor layer or a gate electrode having the MIS structure.

Also, in the first to third embodiments and their variations, an alternating-current switching circuit is illustrated as a circuit in which the bidirectional switch is employed. The present invention is also applicable to, for example, a bidirectional switch circuit which can be employed in a matrix inverter or a drive circuit for a plasma display panel.

As described above, the bidirectional switch and its driving method of the present invention does not require a diode connected in series, so that the ON-resistance is low and the power loss is small. Therefore, the bidirectional switch is useful for an alternating-current switch circuit, a matrix inverter, a drive circuit for a plasma display panel, or the like.

What is claimed is:

1. A bidirectional switch comprising:
a first field-effect transistor having a first gate terminal, a first drain terminal, and a first source terminal;
a second field-effect transistor having a second gate terminal, a second drain terminal, and a second source terminal electrically connected to the first source terminal; and
a switch controller for controlling a conductive state in which current from a bidirectional power supply electrically connected between the first drain terminal and the second drain terminal bidirectionally flows between the first drain terminal and the second drain terminal, and a nonconductive state in which the current does not flow between the first drain terminal and the second drain terminal,
wherein, in the conductive state, the switch controller applies, to the first gate terminal and the second gate terminal, a voltage higher than a threshold voltage of the first field-effect transistor and the second field-effect transistor with reference to a potential at a node to which the first source terminal and the second source terminal are connected, and
in the nonconductive state, the switch controller causes the bidirectional power supply and the first and the second gate terminals to be electrically insulated from each other, and applies, to the first gate terminal and the second gate terminal, a voltage lower than or equal to the threshold voltage with reference to the potential at the node.

2. The bidirectional switch of claim 1, wherein
the switch controller has a control power supply which is electrically connected between the node and the first and second gate terminals, and whose ground is insulated from the bidirectional power supply, and
the control power supply is a variable power supply capable of varying an output voltage, wherein the output voltage is set to be higher than the threshold voltage in the conductive state, and to be lower than or equal to the threshold voltage in the nonconductive state.

3. The bidirectional switch of claim 1, wherein
the switch controller has:
a control power supply electrically connected between the node and the first and second gate terminals and sharing a ground with the bidirectional power supply; and
a switch for electrically cutting off the control power supply from the node and the first and second gate terminals, and
in the conductive state, the switch controller electrically connects the control power supply between the node and the first and second gate terminals, and in the nonconductive state, the switch controller electrically cuts off the control power supply from the node and the first and second gate terminals, and short-circuits the node and the first and second gate terminals.

4. The bidirectional switch of claim 1, wherein the switch controller has a first diode connected between the node and the first ohmic electrode, and a second diode connected between the node and the second ohmic electrode.

5. The bidirectional switch of claim 1, wherein the first field-effect transistor and the second field-effect transistor are made of a nitride semiconductor or silicon carbide.

6. The bidirectional switch of claim 1, wherein the first field-effect transistor and the second field-effect transistor have a normally OFF property in which, when a potential difference between the gate terminal and the source terminal is zero, current does not flow between the drain terminal and the source terminal.

7. The bidirectional switch of claim 1, wherein
the first field-effect transistor and the second field-effect transistor are integrally formed as a semiconductor devices, and
the semiconductor device has:
a semiconductor layer formed on a major surface of a substrate and including a channel region in which electrons travel in a direction parallel to the major surface is formed;
a first ohmic electrode as the first drain terminal and a second ohmic electrode as the second drain terminal, which are formed on the semiconductor layer and are spaced from each other;
a reference electrode as the first source terminal and the second source terminal, which is formed between the first ohmic electrode and the second ohmic electrode on the semiconductor layer;
a first gate electrode as the first gate terminal, which is formed between the first ohmic electrode and the reference electrode on the semiconductor layer; and
a second gate electrode as the second gate terminal, which is formed between the second ohmic electrode and the reference electrode on the semiconductor layer.

8. The bidirectional switch of claim 7, wherein the semiconductor device has a first p-type semiconductor layer formed between the first gate electrode and the semiconductor layer, and a second p-type semiconductor layer formed between the second gate electrode and the semiconductor layer.

9. The bidirectional switch of claim 7, wherein the semiconductor device has an insulating film formed between the first gate electrode and the semiconductor layer and between the second gate electrode and the semiconductor layer.

10. The bidirectional switch of claim 7, wherein the first gate electrode and the second gate electrode are in Schottky-contact with the semiconductor layer.

11. The bidirectional switch of claim 7, wherein the semiconductor device has a normally OFF property in which, when a potential difference between the first gate electrode and the reference electrode and a potential difference between the second gate electrode and the reference electrode are zero, current does not flow between the first ohmic electrode and the second ohmic electrode.

12. The bidirectional switch of claim 7, wherein the switch controller has a first diode connected between the reference electrode and the first ohmic electrode, and a second diode connected between the reference electrode and the second ohmic electrode.

13. The bidirectional switch of claim 12, wherein
the first diode, has an anode electrode which is formed via a p-type anode semiconductor layer on a diode formed region isolated via an isolation region from a region in which the first gate electrode and the second gate electrode are formed in the semiconductor layer, and a first cathode electrode which is formed on the diode formed region, is spaced from the anode electrode, and is electrically connected to the first ohmic electrode, and
the second diode has the anode electrode, and a second cathode electrode which is formed on a side opposite to the first cathode electrode of the anode electrode on the diode formed region and electrically connected to the second ohmic electrode.

14. The bidirectional switch of claim 7, wherein the semiconductor layer is made of a nitride semiconductor or silicon carbide.

15. A bidirectional switch comprising:
a semiconductor device having: a semiconductor layer formed on a major surface of a semiconductor substrate and including a channel region in which electrons travel in a direction parallel to the major surface is formed; a first ohmic electrode, a gate electrode, a first reference electrode, and a second ohmic electrode which are successively formed on the semiconductor layer and are spaced from each other; and a second reference electrode formed on a surface opposite to the major surface of the semiconductor substrate; and
a switch controller for controlling a conductive state in which current from a bidirectional power supply electrically connected between the first ohmic electrode and the second ohmic electrode bidirectionally flows between the first ohmic electrode and the second ohmic electrode, and a nonconductive state in which the current does not flow between the first ohmic electrode and the second ohmic electrode,
wherein, in the conductive state, the switch controller applies, to the gate electrode, a voltage higher than a threshold voltage of the semiconductor device with reference to a potential of the first reference electrode, and
in the nonconductive state, the switch controller short-circuits the gate electrode and the second reference electrode.

16. A method for driving a bidirectional switch comprising a first field-effect transistor having a first gate terminal, a first drain terminal, and a first source terminal, and a second field-effect transistor having a second gate terminal, a second drain terminal, and a second source terminal electrically connected to the first source terminal, the method comprising:
a conduction step of applying, to the first gate terminal and the second gate terminal, a voltage higher than a threshold of the first field-effect transistor and the second field-effect transistor with reference to a potential at a node to which the first source terminal and the second source terminal are connected, so that current from a bidirectional power supply electrically connected between the first drain terminal and the second drain terminal bidirectionally flows between the first drain terminal and the second drain terminal; and
an interruption step of applying, to the first drain terminal and the second drain terminal, a voltage lower than or equal to the threshold voltage with reference to the potential of the node, in a state in which the bidirectional power supply is electrically insulated from the first gate terminal and the second gate terminal, so that current does not flow between the first drain terminal and the second drain terminal.

17. The method of claim 16, wherein
the first field-effect transistor and the second field-effect transistor are integrally formed as a semiconductor devices, and
the semiconductor device has:
a semiconductor layer formed on a major surface of a substrate and including a channel region in which electrons travel in a direction parallel to the major surface is formed;
a first ohmic electrode as the first drain terminal and a second ohmic electrode as the second drain terminal, which are formed on the semiconductor layer and are spaced from each other;
a reference electrode as the first source terminal and the second source terminal, which is formed between the first ohmic electrode and the second ohmic electrode on the semiconductor layer;
a first gate electrode as the first gate terminal, which is formed between the first ohmic electrode and the reference electrode on the semiconductor layer; and
a second gate electrode as the second gate terminal, which is formed between the second ohmic electrode and the reference electrode on the semiconductor layer.

18. A method for riving a bidirectional switch comprising a semiconductor device having a semiconductor layer formed on a major surface of a semiconductor substrate and including a channel region in which electrons travel in a direction parallel to the major surface is formed, a first, ohmic electrode, a gate electrode, a first reference electrode, and a second ohmic electrode which are successively formed on the semiconductor layer and are spaced from each other, and a second reference electrode formed on a surface opposite to the major surface of the semiconductor substrate, the method comprising:
a conduction step of applying, to the gate electrode, a voltage higher than a threshold of the semiconductor device with reference to a potential of the first reference electrode, so that current from a bidirectional power supply electrically connected between the first ohmic electrode and the second ohmic electrode bidirectionally flows between the first ohmic electrode and the second ohmic electrode; and
an interruption step of short-circuiting the first gate electrode and the second gate electrode so that current does not flow between the first ohmic electrode and the second ohmic electrode.
